(19) United States
(12) Patent Application Publication
(10) Pub. No.: US 2009/0302301 A1
(43) Pub. Date: Dec. 10, 2009

(54) RESISTANCE RAM DEVICE HAVING A CARBON NANO-TUBE AND METHOD FOR MANUFACTURING THE SAME

(76) Inventor: Yun Taek HWANG, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/189,881

(22) Filed: Aug. 12, 2008

(30) Foreign Application Priority Data
Jun. 5, 2008 (KR) 10-2008-0052888

(51) Int. Cl. H01L 45/00; H01L 21/28

(52) U.S. Cl. 257/4; 438/104; 257/E45.003; 257/E21.158

(57) ABSTRACT

A resistance RAM (ReRAM) device and method of manufacturing the same are presented. The ReRAM exhibits an improved set resistance distribution and an improved reset resistance distribution. The ReRAM device includes a lower electrode contact that has at least one carbon nano-tube; and a binary oxide layer formed over the lower electrode contact. The binary oxide layer is for storing information in accordance to two different resistance states of the binary oxide layer.

### CROSS-REFERENCE TO RELATED APPLICATIONS

The present application claims priority to Korean patent application number 10-2008-0052888 filed on Jun. 5, 2008, which is incorporated herein by reference in its entirety.

### BACKGROUND OF THE INVENTION

The present invention relates to a memory device, more particularly, to a resistance RAM device having an improved Set resistance distribution and a Reset resistance distribution, along with a method for manufacturing the same.

In general, memory devices are largely divided between volatile RAM (random access memory) that loses stored information when power is interrupted and non-volatile ROM (read-only memory) that can continuously maintain the stored state of information even when power is interrupted. RAM devices include DRAM (dynamic RAM) and SRAM (static RAM), whereas ROM devices include flash memory such as an EEPROM (electrically erasable and programmable ROM).

It is well known in the art, that although the DRAM is an excellent memory device, almost all memory devices must also have high charge storing capacities. As a result, it is difficult to obtain a high integration level for a DRAM because the surface area of an electrode must be increased. Further, in flash memory devices, relatively high operation voltages are required as compared to source voltages due to the fact that two gates are stacked on each other. Accordingly, it is difficult to accomplish a high integration level in a flash memory device because a separate booster circuit is needed to form the necessary voltage for write and delete operations.

Due to these limitations, considerable amounts of research and development has been undertaken to develop novel memory devices having a simple configurations capable of accomplishing a high level of integration while retaining the desirable characteristics of non-volatile memory devices. Novel devices that are strongly expected to be next generation memory components includes, at present, PRAM (phase change RAM), ReRAM (resistance RAM) and MRAM (magnetic RAM). The ReRAM device is a memory device that has a binary transition metal oxide (hereinafter, simply referred to as “binary oxide layer”) capable of storing data in accordance to two different resistance state. The ReRAM device has non-volatile memory device characteristics as well as it has the inherent advantage of being a simple structure.

This ReRAM device can be used to store information in the binary oxide layer by changing from an electrically non-conductable OFF-state of high resistance to an electrically conductable ON-state of low resistance as an arbitrary electrical signal is applied to the binary oxide layer.

More specifically, FIG. 1 is a graph illustrating a driving operation of the ReRAM device. As shown, when a specific voltage is applied to the binary oxide layer, the binary oxide layer is transitioned from a low resistance state to a high resistance state. As a result of this transition the current drops given the same applied voltage. The current applied during this procedure is called as “reset current (Ireset)”. When an arbitrary voltage is applied to the binary oxide layer transitioned to the high resistance state, the binary oxide layer is transitioned back again from the high resistance state to the low resistance state. As a result the current increases. The current applied during this procedure is called as “set current (Iset)”. Therefore, the ReRAM device is capable of storing information in accordance to the resistivity state in that the binary oxide layer. The resistivity state in that the binary oxide layer of the ReRAM device may be either electrically non-conductable or electrically conductable.

Meanwhile, it is important to reduce the reset current in this ReRAM devices. Particularly, it is desirable to improve a set resistance distribution and a reset resistance distribution.

However, conventional ReRAM devices exhibit a number of critical problems in that the variation in distribution of set/reset voltages (Vset/Vreset) applied to the binary oxide layer is large and that the distribution of set/reset resistances (Rset/Rreset) is also irregular.

### SUMMARY OF THE INVENTION

Embodiments of the present invention are directed to a resistance RAM device having an improved set resistance distribution and a reset resistance distribution along with a method for manufacturing the same.

Embodiments of the present invention are also directed to a resistance RAM device capable of reducing a reset current and a method for manufacturing the same.

Embodiments of the present invention are also directed to a resistance RAM device capable of enhancing a sensing margin and enhancing the reliability by reducing the reset current and by improving set resistance distribution and reset resistance distribution, and a method for manufacturing the same.

In another embodiment, a resistance RAM device comprises a lower electrode contact; and a binary oxide layer formed over the lower electrode contact and storing information in accordance to two different resistivities, wherein the lower electrode contact includes at least one carbon nano-tube.

The lower electrode contact may be formed of a single layer of at least one carbon nano-tube or a dual layer of a metal layer and at least one carbon nano-tube.

Each carbon nano-tube may be formed of either a single-wall carbon nano-tube or a multi-wall carbon nano-tube.

In another embodiment, a resistance RAM device comprises a switching device formed over a semiconductor substrate; a lower electrode contact connected with the switching device and formed including at least one carbon nano-tube; a binary oxide layer formed over the lower electrode contact; an upper electrode formed over the binary oxide layer; and a metal wiring in contact with the upper electrode.

The switching device may be a transistor.

The lower electrode contact may be formed of a single layer of at least one carbon nano-tube or formed of a dual layer of a metal layer and the layer of at least one carbon nano-tube.

Each carbon nano-tube is formed of a single-wall carbon nano-tube or a multi-wall carbon nano-tube.

The binary oxide layer may be formed of any one of NiO, TiO₂, ZnO₂, ZrO₂, Nb₂O₅, Al₂O₃ and Ta₂O₅. The binary oxide layer may have a dopant comprising of any one of Ti, Ni, Al, Au, Pt, Ag, Zn and Co.

The upper electrode may be formed of Pt, Ni, W, Au, Ag, Cu, Zn, Al, Ta, Ru and Ir, or alloys thereof.

The resistance RAM device may further comprise a lower electrode formed between the lower electrode contact and the binary oxide layer.

The lower electrode may be formed of Pt, Ni, W, Au, Ag, Cu, Zn, Al, Ta, Ru and Ir, or alloys thereof.

Another embodiment is a method for manufacturing a resistance RAM device that comprises forming a lower electrode contact; and forming a binary oxide layer for storing information according to two different resistance state over the lower electrode contact, wherein the lower electrode contact is formed so as to include at least one carbon nano-tube.

The lower electrode contact may be formed of a single layer of at least one carbon nano-tube or a dual layer of a metal layer and at least one carbon nano-tube.

The carbon nano-tube may be formed of a single-wall carbon nano-tube or a multi-wall carbon nano-tube.

In still another embodiment, a method for manufacturing a resistance RAM device comprises forming an insulation layer having a contact hole over a semiconductor substrate provided with a switching device; forming a lower electrode contact including at least one carbon nano-tube within the contact hole; forming a stacked pattern of a binary oxide layer and an upper electrode over the lower electrode contact; and forming a metal wiring in contact with the stacked pattern.

The method may further comprise depositing a catalyst layer within the contact hole, after the step of forming the insulation layer having the contact hole and before the step of forming the lower electrode contact.

The catalyst layer may be formed of any one of Ni, Fe, Co, Pt, Mo, W, Yt, Au, Pd, Ru and Mn or alloys thereof.

The catalyst layer may be formed in a thickness of 3-50 nm.

The lower electrode contact may be formed of a single layer of at least one carbon nano-tube or a dual layer of a metal layer and at least one carbon nano-tube.

The carbon nano-tube may be formed of a single-wall carbon nano-tube or a multi-wall carbon nano-tube.

The binary oxide layer may be formed of any one of NiO, TiO₂, ZnO₂, ZrO₂, Nb₂O₅, Al₂O₃ and Ta₂O₅. The binary oxide layer may be doped with any one of Ti, Ni, Al, Au, Pt, Ag, Zn and Co.

The upper electrode may be formed of Pt, Ni, W, Au, Ag, Cu, Zn, Al, Ta, Ru and Ir, or alloys thereof.

The method may further comprise forming a lower electrode, after the step of forming the lower electrode contact and before the step of forming the stacked pattern.

The lower electrode may be formed of Pt, Ni, W, Au, Ag, Cu, Zn, Al, Ta, Ru and Ir, or alloys thereof.

### BRIEF DESCRIPTION OF THE DRAWINGS

FIG. 1 is a view illustrating driving of a resistance RAM device.

FIG. 2 is a cross-sectional view illustrating a resistance RAM device in accordance with an embodiment of the present invention.

FIG. 3 is a cross-sectional view illustrating an example of a lower electrode contact in the resistance RAM device in accordance with an embodiment of the present invention.

FIG. 4 is a cross-sectional view illustrating another example of a lower electrode contact in the resistance RAM device in accordance with an embodiment of the present invention.

FIGS. 5A through 5D are cross-sectional views illustrating the steps of a method for manufacturing a resistance RAM device in accordance with an embodiment of the present invention.

FIG. 6 is a cross-sectional view illustrating a resistance RAM device in accordance with another embodiment of the present invention.

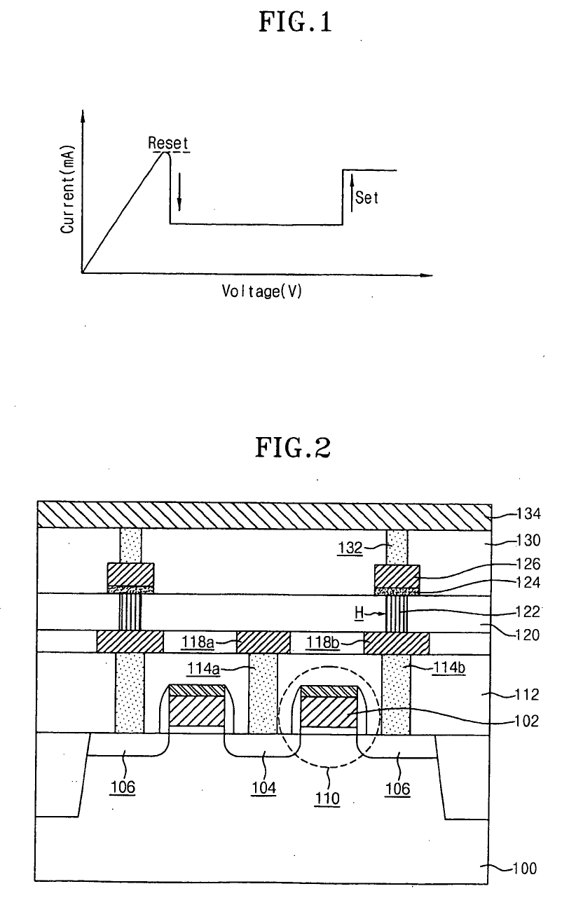

### DESCRIPTION OF SPECIFIC EMBODIMENTS

Hereinafter, preferred embodiments of the present invention will be described in detail with reference with accompanying drawings.

FIG. 2 is a cross-sectional view illustrating a resistance RAM device in accordance with an embodiment of the present invention. As shown, the resistance RAM device in accordance with an embodiment of the present invention includes a switching device 110 comprised of a transistor, a lower electrode contact 122 electrically connected with the switching device 110 and a binary oxide layer 124 formed over the lower electrode contact 122. The switching device 110 formed of a transistor structure includes a gate area 102, a source area 104 and a drain area. The lower electrode contact 122 is formed by vertically growing at least one carbon nano-tube within a hole H formed so as to expose a metal pad 118b. The binary oxide layer 124 may be formed of any one of NiO, TiO₂, ZnO₂, ZrO₂, Nb₂O₅, Al₂O₃ and Ta₂O₅, and has a dopant that may be formed of any one of Ti, Ni, Al, Au, Pt, Ag, Zn and Co.

In FIG. 2, reference numeral 100 denotes a semiconductor substrate, reference numeral 112 denotes a first interlayer dielectric layer, reference numerals 114a and 114b denote first and second contact plugs, reference numeral 116 denotes a first insulation layer, reference numeral 118a denotes a source line, reference numeral 120 denotes a second insulation layer, reference numeral 126 denotes an upper electrode, reference numeral 130 denotes a second interlayer dielectric layer, reference numeral 132 denotes an upper electrode contact, and reference numeral 134 denotes a bit line.

In the resistance RAM device of the present invention, in relation to the fact that the lower electrode contact 122 is formed of at least one carbon nano-tube, the number of carbon nano-tube filaments formed in the binary oxide layer is noticeably reduced at the time of operation. Therefore, it is possible to reduce the reset current and to improve set resistance distribution and reset resistance distribution.

Since the binary oxide layer is an insulating material having a large resistance, then the current is expected to be relatively low within this layer. However, conductors within this insulating layer form an alternate current pathway such as the carbon nano-tube filaments when a specific voltage is applied. At this time, the number of the filament determines the contact area between the lower electrode contact and the binary oxide layer. For example, the smaller contact area between the lower electrode contact and the binary oxide layer decreases the number of the filaments formed within the binary oxide layer.

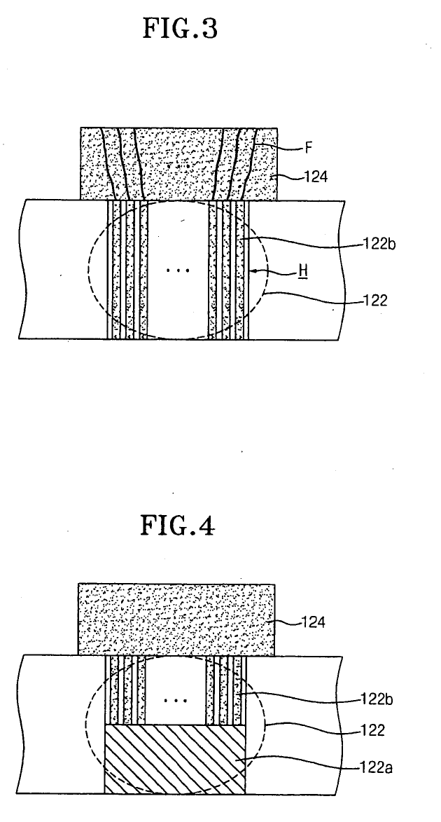

Herein, the carbon nano-tube has a graphite lattice which is circularly rolled with a nano-scale diameter, and is known to exhibit either metal or semiconductor characteristics depending on angle and structure in which the graphite lattice is rolled. The carbon nano-tube may be divided into a single-wall carbon nano-tube and a multi-wall carbon nano-tube having a number of rolled walls. Also, each carbon nano-tube may have a diameter of tens nm scale and a growth length of minimum hundreds nm to maximum several mm scale. As shown in FIG. 3, carbon nano-tubes are not grown within the hole H as a single composite aggregate, but rather these carbon nano-tubes are grown as individual carbon nano-tubes spaced next to one another.

Since the filament F that forms the current path is formed at a contact point between the vertically grown carbon nano-tube 122b and the binary oxide layer 124, then the actual contact area between the lower electrode contact 122 constituted of the carbon nano-tube 122b and the binary oxide layer 124 becomes relatively very small, as compared to the more conventional case in that the lower electrode contact is formed of polysilicon or metal.

Therefore, the resistance RAM device in accordance with an embodiment of the present invention having the lower electrode contact composed of the carbon nano-tube filaments can substantially reduce the reset current because the contact area between the lower electrode contact and the binary oxide layer is reduced. Further the present invention having the lower electrode contact composed of the carbon nano-tube filaments can substantially equalize the set resistance distribution and the reset resistance distribution since the number of the filaments is small.

In one embodiment of the present invention of the resistance RAM device, the lower electrode contact may comprise a single layer of the carbon nano-tube. Another embodiment of the lower electrode contact may comprise a dual layer of a metal layer 122a and the carbon nano-tube 122b as shown in FIG. 4. In this case, the metal layer 122a is disposed below the carbon nano-tube 122b.

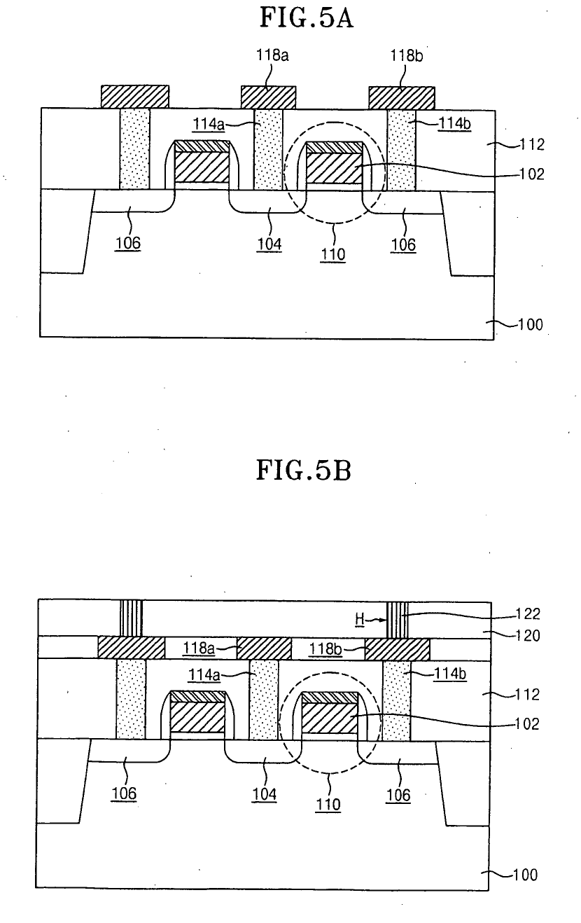

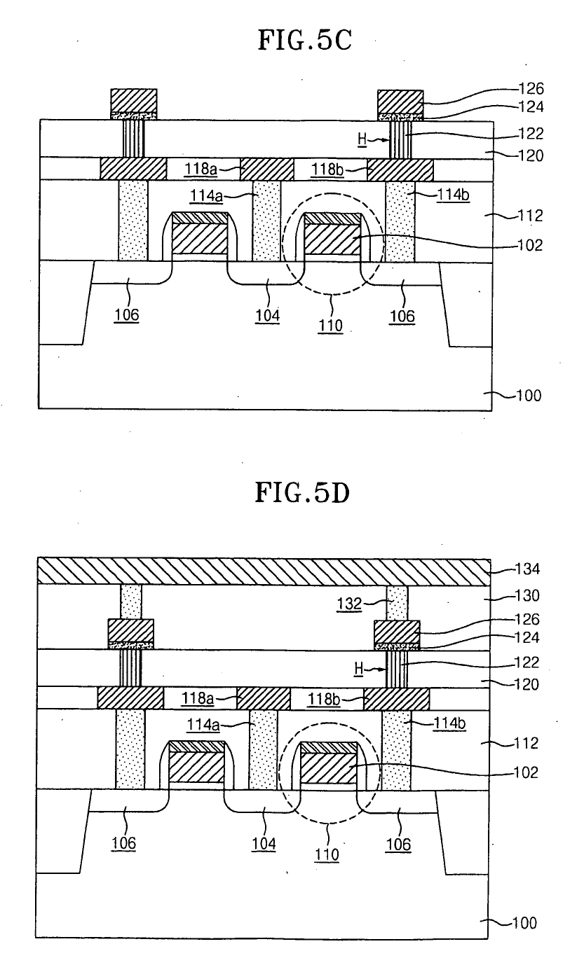

FIGS. 5A through 5D are cross-sectional views illustrating the steps of a method for manufacturing a resistance RAM device in accordance with an embodiment of the present invention. A detailed description thereof is as follows.

Referring to FIG. 5A, a switching device 110 comprising a transistor including the gate area 102, the source area 104 and the drain area 106 is formed over the semiconductor substrate 100. After forming the first interlayer dielectric layer 112 over the semiconductor substrate so as to cover the switching device 110, the first and second contact plugs 114a and 114b are formed through the first interlayer dielectric layer 112 to contact with the source area 104 and the drain area 106, respectively.

After forming the first insulation layer 116 over the first interlayer dielectric layer 112 including the first and second contact plugs 114a and 114b, the source line 118a is then formed to contact with the first contact plug 114a and with the source area 104. The metal pad 118b in contact with the second contact plug 114b is formed so as to be in contact with the drain area 106. The metal pad 118b is formed within the first insulation layer 116 according to, for example, a Damascene inlay process.

Referring to FIG. 5B, after forming the second insulation layer 120 over the first insulation layer 116 including the source line 118a and the metal pad 118b, the hole H for exposing the metal pad 118b is formed by etching the second insulation layer 120. By growing the carbon nano-tube within the hole H, the lower electrode contact in contact with the metal pad 118b is formed. The growth of the carbon nano-tube, i.e. the material for the lower electrode contact can be carried out in the following manner.

First a catalyst layer is deposited over the metal pad 118b at the bottom surface of the hole H. The catalyst layer may be formed of any one of Ni, Fe, Co, Pt, Mo, W, Yt, Au, Pd, Ru and Mn or alloys thereof. This catalyst layer may be deposited in a thickness of 3-50 nm by using, for example, plasma enhanced chemical vapor deposition (PECVD) or metal organic chemical vapor deposition (MOCVD) techniques. In this case, the catalyst layer is mostly deposited over the metal pad 118b exposed by the hole H, but relatively not deposited over the oxide layer, i.e. material for the second insulation layer 120. Since the catalyst layer is deposited in very thin thickness of 3-50 nm, then the catalyst layer is not deposited in a relative uniform thickness, but is rather deposited in a pattern of seeds scattered over the metal pad 118b.

The catalyst layer is for aiding in the control of the growth of the carbon nano-tube in the following process. In particular the catalyst layer is used to control the thickness and distribution thereof which has a large influence on growth size and distribution of the carbon nano-tubes. For example, a thicker catalyst layer results in a larger growth size of the carbon nano-tube and more distribution of the catalyst layer results in larger distribution of the carbon nano-tubes.

Next, the carbon nano-tube is vertically grown within the hole H of which bottom surface is deposited with the catalyst layer. The carbon nano-tube can be grown in a shape of a single-wall carbon nano-tube or a multi-wall carbon nano-tube, and can be grown with a length of hundreds nm to several mm so as to fill in the hole H.

Referring to FIG. 5C, after sequentially depositing binary oxide layer material and upper electrode material over the second insulation layer 120 formed with the lower electrode contact 122 of the carbon nano-tube, a stacked pattern of the pattern shaped binary oxide layer 124 and upper electrode 126 is formed by patterning the binary oxide layer material and upper electrode material. The binary oxide layer 124 comprises of any one of NiO, TiO₂, ZnO₂, ZrO₂, Nb₂O₅, Al₂O₃ and Ta₂O₅, and is preferably doped with any one dopant of Ti, Ni, Al, Au, Pt, Ag, Zn and Co. The upper electrode 126 comprises any one of Pt, Ni, W, Au, Ag, Cu, Zn, Al, Ta, Ru and Ir, or alloys thereof.

Referring to FIG. 5D, after forming the second interlayer dielectric layer 130 over the second insulation layer 120 including the stacked pattern of the binary oxide layer 124 and the upper electrode 126, the upper electrode contact 132 in contact with the upper electrode 126 is formed within the second interlayer dielectric layer 130 in accordance to known processes. After depositing a metal layer over the second interlayer dielectric layer 130 including the upper electrode contact 132, a metal wiring is formed that connects with the upper electrode contacts arranged in one direction, i.e. the bit line 134 is formed by patterning the metal layer.

After that, though not shown, a series of well known follow-up processes is sequentially performed to complete the manufacture of the resistance RAM device in accordance with an embodiment of the present invention.

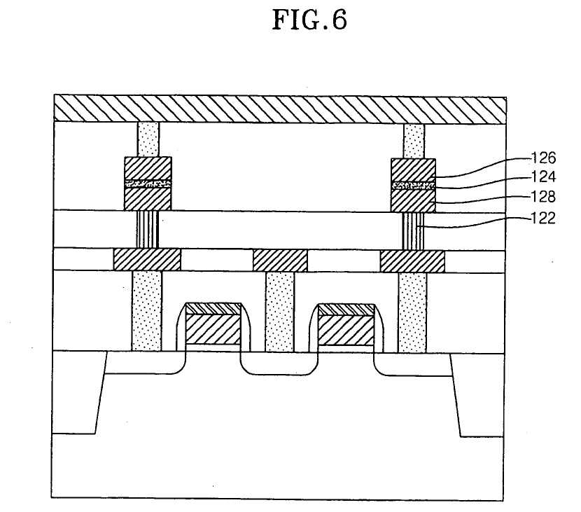

FIG. 6 is a cross-sectional view illustrating a resistance RAM device in accordance with another embodiment of the present invention.

As shown, the resistance RAM device in accordance with another embodiment of the present invention has, as compared to previous embodiment, a structure where a separate lower electrode 128 is interposed between the lower electrode contact 122 and the binary oxide layer 124. The lower electrode 128 may be formed of any one of Pt, Ni, W, Au, Ag, Cu, Zn, Al, Ta, Ru and Ir, or alloys thereof, like the upper electrode 126.

Besides, other components are the same as those of the previous embodiment and thus are not described in detail.

As in the previous embodiment, the resistance RAM device in accordance with another embodiment of the present invention can also reduce the reset current and improve set resistance distribution and reset resistance distribution in relation to the fact that the lower electrode contact 122 is formed of the carbon nano-tube.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A resistance RAM device, comprising:
a lower electrode contact including at least one carbon nano-tube; and
a binary oxide layer formed over the lower electrode contact and storing information in accordance to at least two distinct resistance states of the binary oxide layer.

2. The resistance RAM device according to claim 1, wherein the lower electrode contact is formed of a single layer of at least one carbon nano-tube.

3. The resistance RAM device according to claim 1, wherein the lower electrode contact is formed of a dual layer of a metal layer and a layer of at least one carbon nano-tube.

4. The resistance RAM device according to claim 1, wherein the carbon nano-tube is either a single-wall carbon nano-tube or a multi-wall carbon nano-tube.

5. A resistance RAM device, comprising:
a switching device formed over a semiconductor substrate;
a lower electrode contact connected with the switching device and formed including at least one carbon nano-tube;
a binary oxide layer formed over the lower electrode contact;
an upper electrode formed over the binary oxide layer; and
a metal wiring in contact with the upper electrode.

6. The resistance RAM device according to claim 5, wherein the switching device is a transistor.

7. The resistance RAM device according to claim 5, wherein the lower electrode contact is formed of a single layer of at least one carbon nano-tube.

8. The resistance RAM device according to claim 5, wherein the lower electrode contact is a dual layer of a metal layer and a carbon nano-tube layer.

9. The resistance RAM device according to claim 5, wherein the carbon nano-tube is a single-wall carbon nano-tube or a multi-wall carbon nano-tube.

10. The resistance RAM device according to claim 5, wherein the binary oxide layer is selected from the group consisting of NiO, TiO₂, ZnO₂, ZrO₂, Nb₂O₅, Al₂O₃ and Ta₂O₅.

11. The resistance RAM device according to claim 5, wherein the binary oxide layer comprises a dopant.

12. The resistance RAM device according to claim 11, wherein the dopant is selected from the group consisting of Ti, Ni, Al, Au, Pt, Ag, Zn and Co.

13. The resistance RAM device according to claim 5, wherein the upper electrode is selected from the group consisting of Pt, Ni, W, Au, Ag, Cu, Zn, Al, Ta, Ru, Ir, and alloys thereof.

14. The resistance RAM device according to claim 5, further comprising a lower electrode formed between the lower electrode contact and the binary oxide layer.

15. The resistance RAM device according to claim 14, wherein the lower electrode is selected from the group consisting of Pt, Ni, W, Au, Ag, Cu, Zn, Al, Ta, Ru and Ir, or alloys thereof.

16. A method for manufacturing a resistance RAM device, comprising the steps of:
forming a lower electrode contact that includes at least one carbon nano-tube; and
forming a binary oxide layer over the lower electrode contact, the binary oxide for storing information in accordance to two different resistance states.

17. The method according to claim 16, wherein the lower electrode contact is formed of a single layer of the carbon nano-tube.

18. The method according to claim 16, wherein the lower electrode contact is a dual layer of a metal layer and a carbon nano-tube layer.

19. The method according to claim 16, wherein the carbon nano-tube is a single-wall carbon nano-tube or a multi-wall carbon nano-tube.

20. A method for manufacturing a resistance RAM device, comprising the steps of:
forming an insulation layer having a contact hole over a semiconductor substrate provided with a switching device;
forming a lower electrode contact including carbon nano-tubes within the contact hole;
forming a binary oxide layer and an upper electrode over the lower electrode contact; and
forming a metal wiring in contact with the upper electrode.

21. The method according to claim 20, further comprising, the step of depositing a catalyst layer within the contact hole, after the step of forming the insulation layer having the contact hole and before the step of forming the lower electrode contact.

22. The method according to claim 21, wherein the catalyst layer is selected from the group consisting of Ni, Fe, Co, Pt, Mo, W, Yt, Au, Pd, Ru, Mn and alloys thereof.

23. The method according to claim 21, wherein the catalyst layer has a thickness of 3-50 nm.

24. The method according to claim 20, wherein the lower electrode contact is formed of the carbon nano-tubes.

25. The method according to claim 20, wherein the lower electrode contact is formed of a dual layer of a metal layer and the carbon nano-tubes.

26. The method according to claim 20, wherein each carbon nano-tube is a single-wall carbon nano-tube or a multi-wall carbon nano-tube.

27. The method according to claim 20, wherein the binary oxide layer is selected from the group consisting of NiO, TiO₂, ZnO₂, ZrO₂, Nb₂O₅, Al₂O₃ and Ta₂O₅.

28. The method according to claim 20, wherein the binary oxide layer is selected from the group consisting one of Ti, Ni, Al, Au, Pt, Ag, Zn and Co.

29. The method according to claim 20, wherein the upper electrode is selected from the group consisting of Pt, Ni, W, Au, Ag, Cu, Zn, Al, Ta, Ru and Ir, or alloys thereof.

30. The method according to claim 20, further comprising the step of forming a lower electrode, after the step of forming the lower electrode contact and before the step of forming the binary oxide layer and the upper electrode.

31. The method according to claim 30, wherein the lower electrode is selected from the group consisting of Pt, Ni, W, Au, Ag, Cu, Zn, Al, Ta, Ru, Ir, and alloys thereof.
